(19) United States
(12) Patent Application Publication
(10) Pub. No.: US 2026/0296163 A1
(43) Pub. Date: Oct. 1, 2026

(54) ELECTRIFIED VEHICLE

(71) Applicant: TOYOTA JIDOSHA KABUSHIKI KAISHA, Toyota-shi (JP)

(72) Inventors: Yosei SAKAMOTO, Toyota-shi (JP); Ryota KOIKE, Nisshin-shi (JP)

(73) Assignee: TOYOTA JIDOSHA KABUSHIKI KAISHA, Toyota-shi (JP)

(21) Appl. No.: 19/545,201

(22) Filed: Feb. 20, 2026

(30) Foreign Application Priority Data
Mar. 28, 2025 (JP) 2025-056325

(51) Int. Cl. B60K 1/04; H05K 7/20

(52) U.S. Cl. CPC B60K 1/04; H05K 7/20863; H05K 7/20881; B60K 2001/0411

(57) ABSTRACT

In an electrified vehicle in which an electric drive unit that receives power supply from a high-voltage battery to generate a driving force for traveling, a water module that distributes cooling water in a circulation circuit of the cooling water, and a refrigerant module that includes an air-cooled condenser that cools a refrigerant for air conditioning by heat exchange with outside air are installed in a front compartment provided in a vehicle front portion, the water module and the refrigerant module are disposed in a vehicle up-down direction such that the refrigerant module is positioned in front of the electric drive unit and above the water module in the vehicle.

### CROSS-REFERENCE TO RELATED APPLICATION

This application claims priority to Japanese Patent Application No. 2025-056325 filed on Mar. 28, 2025. The disclosure of the above-identified application, including the specification, drawings, and claims, is incorporated by reference herein in its entirety.

### BACKGROUND

### 1. Technical Field

The present disclosure relates to an electrified vehicle.

### 2. Description of Related Art

In an electrified vehicle, there is an electrified vehicle including an electric drive unit in which a motor for traveling and gears are integrated. Japanese Unexamined Patent Application Publication No. 2015-9724 (JP 2015-9724 A) discloses an electrified vehicle. In the electrified vehicle, the electric drive unit is installed inside a front compartment in a front portion of the vehicle, and an inverter case that accommodates an inverter is installed above the electric drive unit of the vehicle.

### SUMMARY

In addition to the electric drive unit and the inverter, equipment such as a thermal module that constitutes a cooling system of the vehicle is also installed inside the front compartment. In a case where a refrigerant module including an air-cooled condenser is densely installed inside the front compartment together with a large number of pieces of equipment, the condenser may not be easily hit by traveling wind, and a cooling efficiency of the refrigerant may be reduced.

In an electrified vehicle that solves the above-described problem, an electric drive unit configured to generate a driving force for traveling using power supplied from a high-voltage battery, a water module configured to distribute cooling water in a circulation circuit of the cooling water, and a refrigerant module including an air-cooled condenser that cools a refrigerant for air conditioning by heat exchange with outside air are installed inside a front compartment provided in a front portion of the vehicle. The water module and the refrigerant module are installed in front of the electric drive unit of the vehicle and are arranged in an up-down direction of the vehicle such that the refrigerant module is positioned above the water module of the vehicle.

The electrified vehicle has an effect that the electric drive unit, the water module, and the refrigerant module can be disposed inside the front compartment so that the refrigerant can be efficiently cooled.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram schematically showing an arrangement of an electrified vehicle as an embodiment as viewed from above the vehicle;

FIG. 2 is a diagram schematically showing an arrangement of the front compartment of the electrified vehicle of FIG. 1 as viewed from a left side of the vehicle; and

FIG. 3 is a diagram schematically showing an arrangement of the front compartment of the electrified vehicle of FIG. 1 as viewed from above the vehicle.

### DETAILED DESCRIPTION OF EMBODIMENTS

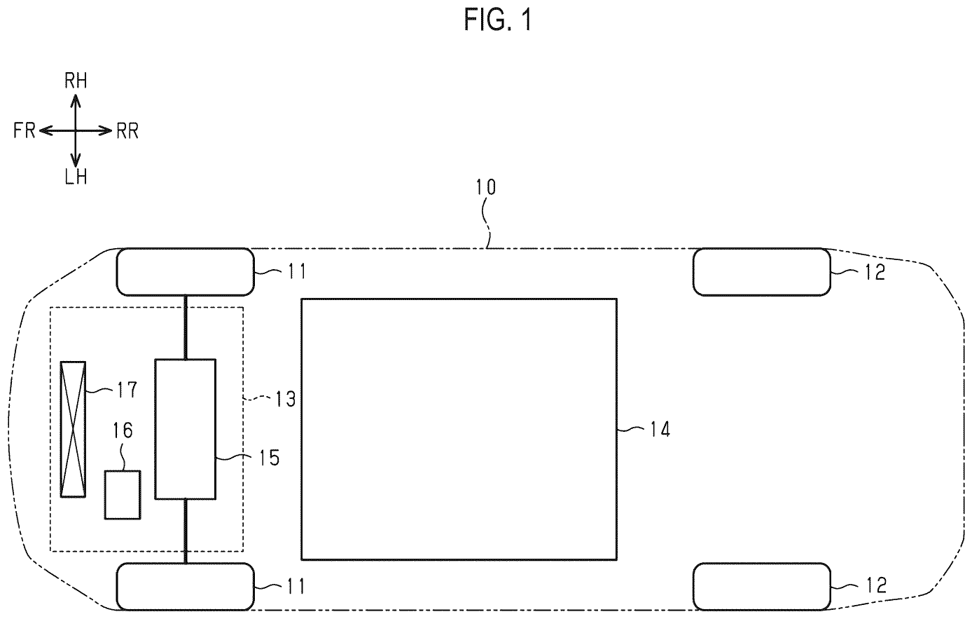

Hereinafter, an embodiment of the electrified vehicle will be described in detail with reference to FIGS. 1 to 3. In each of the drawings, “FR” in a direction indicated by an arrow represents a vehicle front side, “RR” represents a vehicle rear side, “RH” represents a vehicle right side, “LH” represents a vehicle left side, “UP” represents a vehicle upper side, and “DW” represents a vehicle lower side.

### Configuration of Electrified Vehicle 10

The electrified vehicle 10 of the present embodiment shown in FIG. 1 includes four wheels including left and right front wheels 11 and left and right rear wheels 12. The electrified vehicle 10 is configured as a front-wheel drive battery electrified vehicle that travels by driving the left and right front wheels 11. The electrified vehicle 10 includes two electric systems of a high voltage and a low voltage.

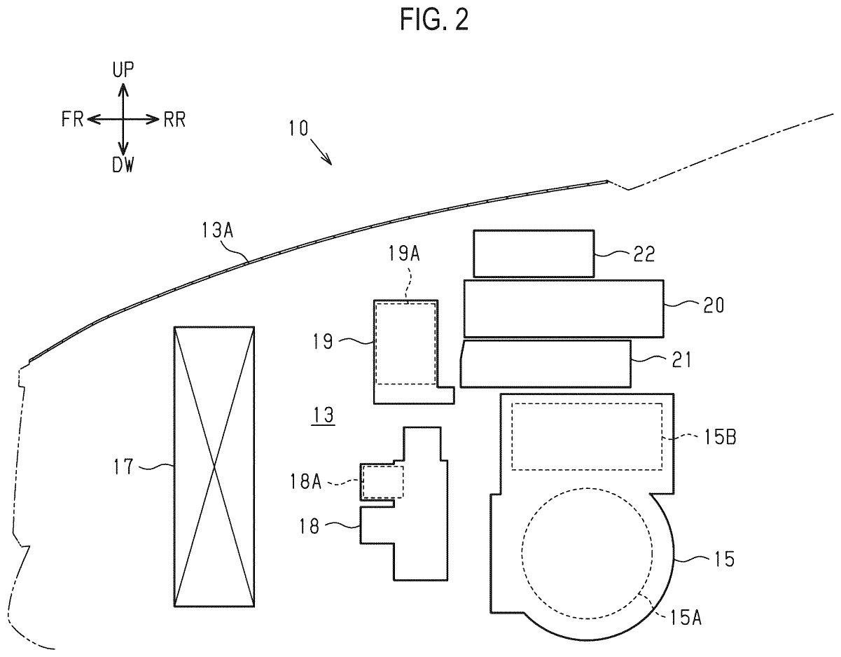

A front compartment 13 is provided in a vehicle front portion of the electrified vehicle 10. The vehicle front portion here refers to a portion of the electrified vehicle 10 in front of a vehicle cabin in which an occupant is seated. The front compartment 13 is covered with a bonnet 13A (see FIG. 2) that is openable and closable above the vehicle. The front compartment 13 is configured such that the inside can be accessed from above the vehicle by opening the bonnet 13A. A high-voltage battery 14 connected to the high-voltage system of the electrified vehicle 10 is installed under the floor in a portion of the electrified vehicle 10 behind the front compartment 13. On the other hand, an electric drive unit 15 that generates a driving force of the electrified vehicle 10 in response to power supply from the high-voltage battery 14 is installed in the front compartment 13. In the electrified vehicle 10 of the present embodiment, the electric drive unit 15 is configured to drive the left and right front wheels 11. The electric drive unit 15 includes at least a motor 15A (see FIG. 2) that generates a driving force. In the present embodiment, the electric drive unit 15 is configured as a module in which the motor 15A, the gears constituting a speed reduction mechanism and a differential mechanism, and an inverter 15B (see FIG. 2) are accommodated in one case.

Further, a low-voltage battery 16 and a radiator 17 are installed in the front compartment 13. The low-voltage battery 16 is a battery connected to the low-voltage system of the electrified vehicle 10. The radiator 17 is a heat exchanger that cools the cooling water by heat exchange with outside air. The radiator 17 is installed in a portion of the front compartment 13 in front of the vehicle. The low-voltage battery 16 is installed in a portion of the front compartment 13 in front of the electric drive unit 15 and behind the radiator 17 in the vehicle.

### Disposition of High-Voltage Module and Thermal Module

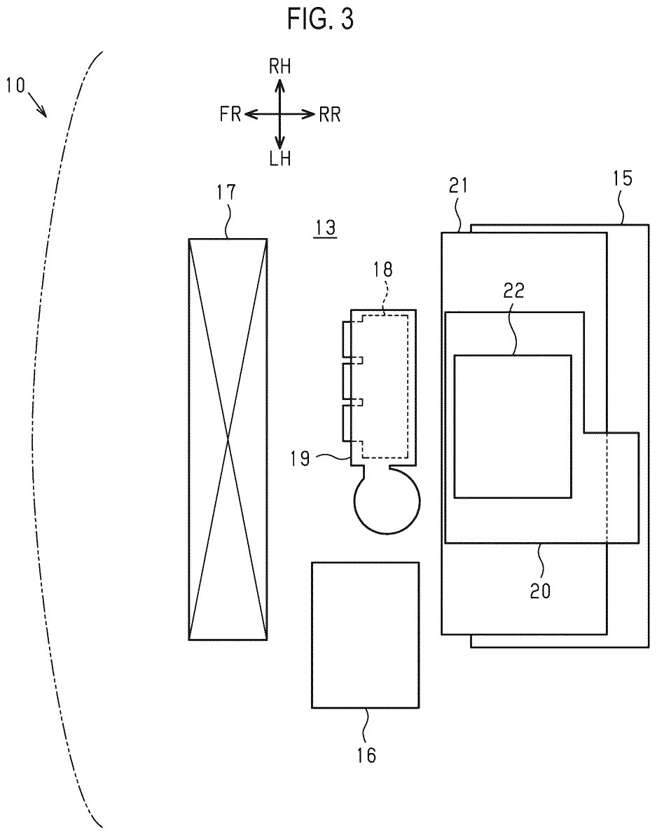

Next, an arrangement of a high-voltage module and a thermal module in the front compartment 13 of the electrified vehicle 10 will be described with reference to FIGS. 2 and 3. FIG. 2 shows an arrangement of the inside of the front compartment 13 as viewed from the left side of the vehicle, and FIG. 3 shows an arrangement of the inside of the front compartment 13 as viewed from above the vehicle. The high-voltage module is a module connected to the high-voltage system of the electrified vehicle 10. The thermal module is a module that distributes a heat transport medium. The electrified vehicle 10 of the present embodiment includes two circuits as a circulation circuit of the heat transport medium, the water circuit in which the cooling water circulates, and the refrigerant circuit in which the refrigerant for air conditioning circulates. The radiator 17 is connected to the water circuit.

The electrified vehicle 10 of the present embodiment includes a water module 18 and a refrigerant module 19 as the thermal module installed in the front compartment 13. The water module 18 is configured to distribute the cooling water. The refrigerant module 19 is configured to distribute the refrigerant. In the present embodiment, the water module 18 is configured as a module that includes each component related to the distribution of the cooling water to each component to which the cooling water is supplied. The components to which the water module 18 distributes the cooling water include the radiator 17, the high-voltage battery 14, and the electric drive unit 15. In the present embodiment, the water module 18 is provided with a plurality of electric pumps that send the cooling water to each component and a plurality of switching valves that switch the flow of the cooling water to each component. The refrigerant module 19 is configured as a module that includes each component related to the distribution of the refrigerant to each component to which the refrigerant is supplied. In the present embodiment, the refrigerant distributed by the refrigerant module 19 is used for air conditioning of the vehicle cabin, cooling of the high-voltage battery 14, and the like. In the present embodiment, the refrigerant module 19 includes a plurality of expansion valves that vaporize the liquefied refrigerant and send the vaporized refrigerant to each component. In addition, in the electrified vehicle 10 of the present embodiment, the refrigerant module 19 includes an air-cooled condenser 19A that cools the refrigerant by heat exchange with outside air, and a modulator that performs gas-liquid separation of the cooled refrigerant. In the present embodiment, the water module 18 is provided with an electric pump 18A that sends the cooling water to the condenser 19A.

On the other hand, the electrified vehicle 10 of the present embodiment includes a distribution module 20 and an in-vehicle charging module 21 as the high-voltage module installed in the front compartment 13. The distribution module 20 is a high-voltage module that distributes the power of the high-voltage battery 14 to each high-voltage device of the electrified vehicle 10 including the inverter 15B. The in-vehicle charging module 21 is a high-voltage module that performs charging control of the high-voltage battery 14. In the present embodiment, the in-vehicle charging module 21 is configured to include a step-down circuit that steps down the power of the high-voltage system and supplies the stepped-down power to the low-voltage system, in addition to a charging circuit for charging control.

In addition, a high-voltage heater module 22 is installed in the front compartment 13. The high-voltage heater module 22 is configured to perform electric heating of the cooling water using the power of the high-voltage battery 14. The high-voltage heater module 22 is a thermal module connected to the circulation circuit of the cooling water and is also a high-voltage module connected to the high-voltage battery 14. In the present embodiment, the high-voltage heater module 22 is configured to heat the cooling water that has passed through the condenser 19A of the refrigerant module 19. The cooling water heated by the high-voltage heater module 22 is used for, for example, heating of the vehicle cabin and heating of the high-voltage battery 14.

Further, the water module 18 and the refrigerant module 19 are installed in front of the electric drive unit 15 in the vehicle. In the electrified vehicle 10 of the present embodiment, the water module 18 and the refrigerant module 19 are disposed in the vehicle up-down direction such that the refrigerant module 19 is positioned above the water module 18 in the vehicle. On the other hand, the low-voltage battery 16 is disposed on the vehicle left side of the water module 18 and the refrigerant module 19.

### Operation of Embodiment

In the electrified vehicle 10 of the present embodiment, two thermal modules of the water module 18 and the refrigerant module 19 are installed in front of the electric drive unit 15 in the front compartment 13. Among these, the refrigerant module 19 includes the air-cooled condenser 19A. A portion of the front compartment 13 in front of the electric drive unit 15 is a portion that relatively easily takes in traveling wind. In addition, a portion of the front compartment 13 above the vehicle is a portion through which the traveling wind easily passes. In the electrified vehicle 10 of the present embodiment, the refrigerant module 19 including the air-cooled condenser 19A is installed in the front compartment 13, particularly in a portion that easily takes in the traveling wind.

### Effect of Embodiment

The electrified vehicle 10 of the present embodiment has the following effects.

(1) In the front compartment 13 of the electrified vehicle 10 of the present embodiment, the electric drive unit 15, the water module 18, and the refrigerant module 19 are installed. The water module 18 and the refrigerant module 19 are disposed in the vehicle up-down direction such that the refrigerant module 19 is positioned in front of the electric drive unit 15 and above the water module 18 in the vehicle. Since the refrigerant module 19 including the air-cooled condenser 19A is disposed in the front compartment 13 in a portion that easily takes in the traveling wind, the refrigerant can be efficiently cooled.

(2) The water module 18 and the refrigerant module 19 are installed in front of the electric drive unit 15, while the high-voltage module is installed above the electric drive unit 15 in the vehicle. Since the water module 18 and the refrigerant module 19 function as a buffer member against the impact, the high-voltage module can be protected from the impact during the collision.

### Other Embodiments

The embodiment described above can be modified and carried out as follows.

The embodiment described above and the following modifications can be carried out in combination within a technically consistent range.
The type and the number of the high-voltage modules installed above the electric drive unit 15 may be appropriately changed.
The electric drive unit 15 may have a configuration other than the following as long as the electric drive unit 15 includes the motor 15A that receives the power supply from the high-voltage battery 14 to generate the driving force of the electrified vehicle 10. For example, the electric drive unit 15 may have a configuration that is separate from the inverter 15B or a configuration that is separate from the gears constituting the speed reduction mechanism and the differential mechanism.
The high-voltage battery 14, the low-voltage battery 16, and the radiator 17 may be disposed at a location different from that in the above-described embodiment.
The electrified vehicle 10 may be configured as a four-wheel drive vehicle that drives the rear wheels 12 by an electric drive unit different from the electric drive unit 15 installed in the front compartment 13 or by an engine.

What is claimed is:

1. An electrified vehicle, wherein:
an electric drive unit configured to generate a driving force for traveling using power supplied from a high-voltage battery, a water module configured to distribute cooling water in a circulation circuit of the cooling water, and a refrigerant module including an air-cooled condenser that cools a refrigerant for air conditioning by heat exchange with outside air are installed inside a front compartment provided in a front portion of the vehicle; and
the water module and the refrigerant module are installed in front of the electric drive unit of the vehicle and are arranged in an up-down direction of the vehicle such that the refrigerant module is positioned above the water module of the vehicle.

2. The electrified vehicle according to claim 1, wherein a high-voltage module connected to the high-voltage battery is installed at a portion above the electric drive unit inside the front compartment of the vehicle.
